(19) United States
(12) Patent Application Publication
(10) Pub. No.: US 2012/0092121 A1
(43) Pub. Date: Apr. 19, 2012

(54) BALANCED TRANSFORMER STRUCTURE

(75) Inventors: Jun-De JIN, Hsinchu City (TW); Tzu-Jin YEH, Hsinchu City (TW); Chewn-Pu JOU, Hsinchu (TW); Fu-Lung HSUEH, Cranbury, NJ (US)

(73) Assignee: TAIWAN SEMICONDUCTOR MANUFACTURING COMPANY, LTD., Hsinchu (TW)

(21) Appl. No.: 12/974,080

(22) Filed: Dec. 21, 2010

Related U.S. Application Data
(60) Provisional application No. 61/393,525, filed on Oct. 15, 2010.

(51) Int. Cl. H01F 27/28

(52) U.S. Cl. 336/232

(57) ABSTRACT

A multi-chip electronic device includes a first winding having a first port (P+) and a second port (P−). The first winding is formed in a metal layer of a first chip. The device further includes a second winding having a third (S+) and a fourth port (S−). The second winding is formed in a metal layer of a second chip. A center tap of the second winding is connected to a reference potential.

### CROSS-REFERENCE TO RELATED APPLICATIONS

The present application claims priority of U.S. Provisional Patent Application Ser. No. 61/393,525, filed on Oct. 15, 2010, which is incorporated herein by reference in its entirety.

### BACKGROUND

The disclosure relates generally to transformers, and more particularly, to transformers used in through chip interface (TCI) applications.

Transformers are commonly used in wireless communications. For example, transformers are frequently used in transceivers in wireless communication devices. In TCI applications and chip-to-chip communications, decreasing path length is one key to increasing bandwidth and reducing dissipation. In three-dimensional integrated circuits (3D ICs), two or more chips may be stacked face-to-face and/or face-to-back and inductively coupled.

FIG. 1a is a circuit diagram of a transformer 100 having the same turn ratio for use in TCI and in 3D IC applications and FIG. 1b is a perspective view of the transformer of FIG. 1a. Transformer 100 includes a primary winding in a first chip 110 having ports P+ and P− and a secondary winding in a second chip 120 having ports S+and S−. The first chip 110 and the second chip 120 may be formed in a 3D IC multi-chip device. For example, second chip 120 may be formed above first chip 110, the first chip 110 being formed above a substrate. The primary winding may represent the transmitter side while the secondary winding represents the receiver side. Without well-defined grounds, transformer 100 tends to exhibit imbalanced differential signals and, as a result, may suffer from noise and interference, lower speeds, higher power consumption, and poor bit error rate.

FIG. 2 is a graph showing voltage (mV) versus time (picoseconds) of transformer 100. The rising time for the input current is 100 picoseconds. With an amplitude difference of around 50 mV and a phase difference of about 0 degrees as shown in FIG. 2, transformer 100 may have poor sensitivity and/or high power consumption issues.

### BRIEF DESCRIPTION OF DRAWINGS

The features, aspects, and advantages of the disclosure will become more fully apparent from the following detailed description, appended claims, and accompanying drawings in which:

FIG. 1a is a circuit diagram of a transformer.

FIG. 1b is a perspective view of the transformer of FIG. 1a.

FIG. 2 is a graph depicting voltage versus time of the transformer of FIGS. 1a and 1b.

FIG. 3 is a circuit diagram of a transformer according to one or more embodiments of the present disclosure.

FIG. 4. is a graph of voltage versus time of a transformer according to one or more embodiments of the present disclosure.

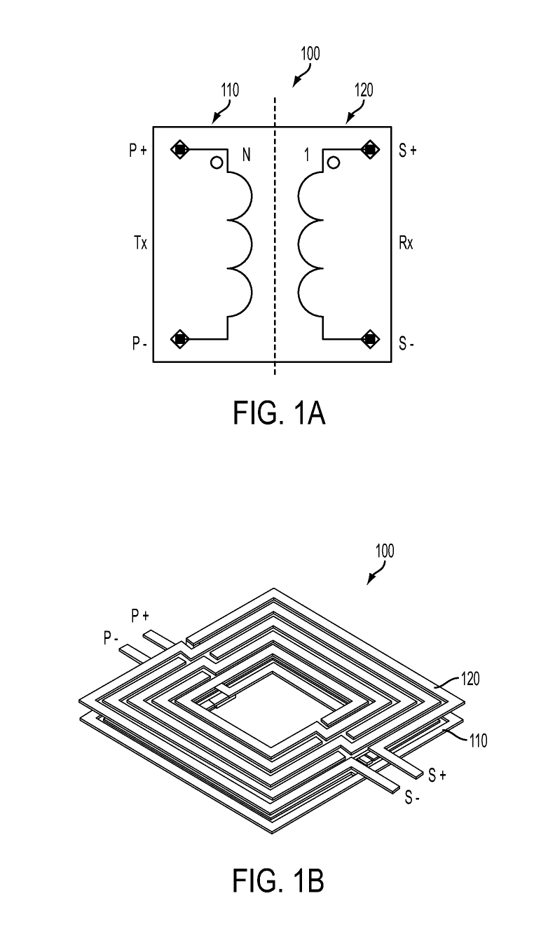

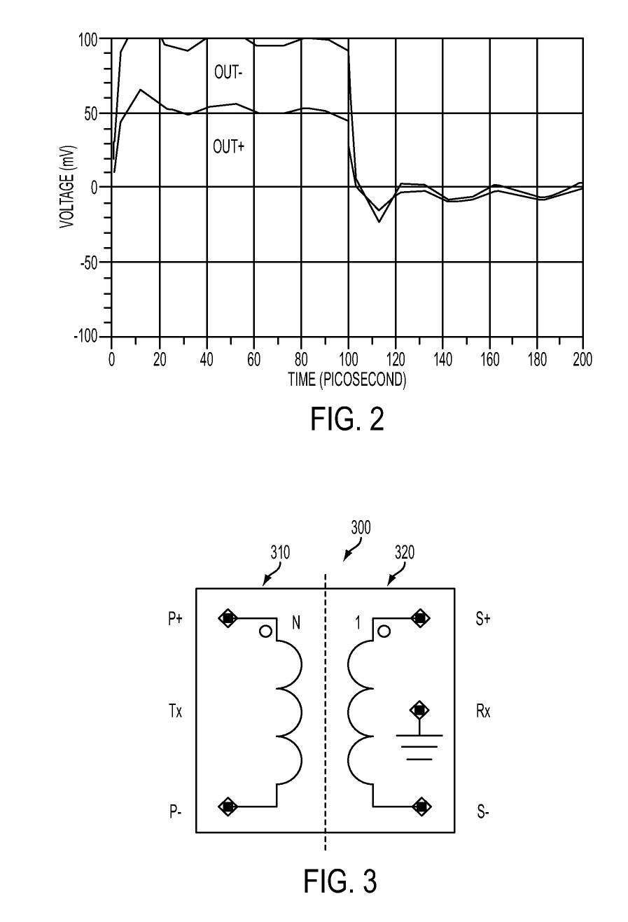

### DETAILED DESCRIPTION

In the following description, numerous specific details are set forth to provide a thorough understanding of embodiments of the present disclosure. However, one having an ordinary skill in the art will recognize that embodiments of the disclosure can be practiced without these specific details. In some instances, well-known structures and processes have not been described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

FIG. 3 is a circuit diagram of a transformer 300 having the same turn ratio according to one or more embodiments of the present disclosure. Transformer 300 includes a primary winding in a first chip 310 having ports P+ and P− and a secondary winding in a second chip 320 having ports S+ and S−. The turn's ratio between the primary winding and the secondary winding depends on the desired gain to be achieved via the transformer 300. For example, the primary winding may consist of two turns while the secondary winding may consist of nine turns. Other turn ratios may be used to provide a desired gain.

The primary and secondary windings may comprise of multiple turns that are connected by metal bridges (not shown). The geometric shape of the turns may correspond to a square shape, for example. The present disclosure, however is not limited to square shapes as other shapes, such as octagonal, rectangular, etc. are also contemplated. It is to be understood that the particular length and width of the square shape is based on a balancing of the inductance value, the turn's ratio, the quality factor and capacitance of the windings.

The primary winding may be formed in a metal layer of the first chip 310 whereas the secondary winding may be formed in a metal layer of the second chip 320, the second chip 320 being formed over a substrate, e.g., a semiconductor substrate. The thicknesses of the metal layers of the first and second chips may range from approximately one micron to approximately three microns, according to some embodiments of the present disclosure. In other embodiments, the primary and secondary windings may be formed on metal layers having other thicknesses. The first metal layer may be vertically displaced from the second metal layer with one or more dielectric and/or semiconductor layers therebetween. Typically, the secondary winding is electrically isolated from the primary winding and electromagnetically coupled to the primary winding. In one exemplary embodiment, the primary winding represents the transmitter side (Tx) while the secondary winding represents the receiver side (Rx).

The first chip 310 and the second chip 320 may be formed in a multi-chip electronic device, e.g., a 3D IC multi-chip device (not shown). In one embodiment, second chip 320 is formed above first chip 310 which, in turn, is formed above a substrate. One skilled in the art understands that the 3D IC multi-chip device may include two or more chips, with each chip having either a transmitter or a receiver.

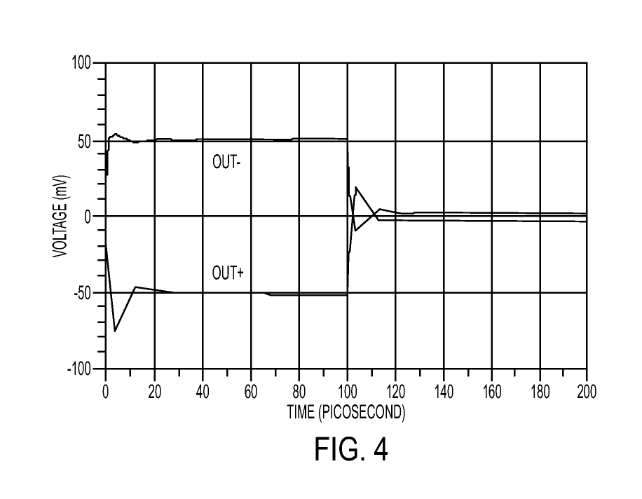

An aspect of embodiments of the present disclosure resides in a center tap of the secondary winding connected to a reference potential, Rx so as to achieve a balanced transformer having balanced differential signals. The reference potential Rx is AC ground, according to one embodiment of the present disclosure. FIG. 4. is a graph showing voltage (mV) versus time (picoseconds) of transformer 300 according to one embodiment of the present disclosure. The rising time for the input current is 100 picoseconds. With an amplitude difference of around 100 mV and phase difference of about 180 degrees, the transformer of the present disclosure produces highly balanced differential output signals.

In the preceding detailed description, the present disclosure is described with reference to specifically exemplary embodiments thereof. It will, however, be evident that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the invention as expressed herein.

What is claimed is:

1. A multi-chip electronic device, comprising:
a first winding having a first port (P+) and a second port (P−), the first winding formed in a metal layer of a first chip; and
a second winding having a third (S+) and a fourth port (S−), the second winding formed in a metal layer of a second chip, wherein a center tap of the second winding is connected to a reference potential.

2. The multi-chip electronic device of claim 1, wherein the first winding is a primary winding and the second winding is a secondary winding.

3. The multi-chip electronic device of claim 1, wherein the second winding is electrically isolated from the first winding and electromagnetically coupled to the first winding.

4. The multi-chip electronic device of claim 1, wherein the reference potential is ground.

5. The multi-chip electronic device of claim 1, wherein the first winding is a transmitter and the second winding is a receiver.

6. The multi-chip electronic device of claim 1, wherein each of the first and second windings comprises multiple turns.

7. The multi-chip electronic device of claim 1, wherein the center tap is formed in the second winding.

8. The multi-chip electronic device of claim 1, wherein the metal layer of the first chip has a thickness in a range from approximately one micron to approximately three microns.

9. The multi-chip electronic device of claim 1, wherein the metal layer of the second chip has a thickness in a range from approximately one micron to approximately three microns.

10. The multi-chip electronic device of claim 1, wherein the metal layer of the first chip is vertically displaced from the metal layer of the second chip with a dielectric layer or semiconductor layer therebetween.

11. A multi-chip transformer, comprising:
a primary winding having a first set of ports, the primary winding formed in a conductive layer of a first chip; and
a secondary winding having a second set of ports, the secondary winding formed in a conductive layer of a second chip, wherein a center tap of the secondary winding is connected to a reference potential.

12. The multi-chip transformer of claim 11, wherein the first set of ports includes a first port (P+) and a second port (P−).

13. The multi-chip transformer of claim 11, wherein the second set of ports includes a third port (S+) and a fourth port (S−).

14. The multi-chip transformer of claim 11, wherein the secondary winding is electrically isolated from the primary winding and electromagnetically coupled to the primary winding.

15. The multi-chip transformer of claim 11, wherein the reference potential is ground.

16. The multi-chip transformer of claim 11, wherein the primary winding is a transmitter and the secondary winding is a receiver.

17. The multi-chip transformer of claim 11, wherein the center tap is formed in the secondary winding.

18. The multi-chip transformer of claim 11, wherein the metal layer of the first chip has a thickness in a range from approximately one micron to approximately three microns.

19. The multi-chip transformer of claim 11, wherein the metal layer of the second chip has a thickness in a range from approximately one micron to approximately three microns.

20. The multi-chip transformer of claim 11, wherein the metal layer of the first chip is vertically displaced from the metal layer of the second chip with a dielectric layer or semiconductor layer therebetween.
